(19) United States
(12) Patent Application Publication
(10) Pub. No.: US 2026/0101608 A1
(43) Pub. Date: Apr. 9, 2026

(54) SEMICONDUCTOR APPARATUS AND METHOD OF MANUFACTURING THE SAME

(71) Applicants: SAMSUNG ELECTRONICS CO., LTD., Suwon-si (KR); INDUSTRY ACADEMY COOPERATION FOUNDATION OF SEJONG UNIVERSITY, Seoul (KR)

(72) Inventors: Young Joon HONG, Seoul (KR); Joonghoon Choi, Seoul (KR)

(73) Assignees: SAMSUNG ELECTRONICS CO., LTD., Suwon-si (KR); INDUSTRY ACADEMY COOPERATION FOUNDATION OF SEJONG UNIVERSITY, Seoul (KR)

(21) Appl. No.: 19/214,829

(22) Filed: May 21, 2025

(30) Foreign Application Priority Data
Oct. 7, 2024 (KR) 10-2024-0135960

(51) Int. Cl. H10H 20/01; G01S 7/481; G01S 17/931; H01S 5/343; H10H 20/815; H10H 20/817; H10H 20/825

(52) U.S. Cl. CPC H10H 20/0137; H01S 5/343; H10H 20/016; H10H 20/815; H10H 20/817; H10H 20/825; G01S 7/4814; G01S 17/931; H01S 2304/04; H01S 2304/12

(57) ABSTRACT

A method of manufacturing a semiconductor apparatus includes: forming a two-dimensional material layer on a substrate layer, wherein the substrate layer includes a nitrogen (N)-polar nitride compound material; forming a plurality of through-holes in the two-dimensional material layer along a thickness direction of the two-dimensional material layer by performing a heat treatment at a process temperature in a process gas atmosphere; epitaxially growing a first semiconductor layer along the thickness direction in the plurality of through-holes of the two-dimensional material layer; and performing epitaxial lateral over-growing, horizontally along a plane perpendicular to the thickness direction, of the first semiconductor layer on the two-dimensional material layer.

### CROSS-REFERENCE TO RELATED APPLICATION

This application is based on and claims priority under 35 U.S. C. § 119 to Korean Patent Application No. 10-2024-0135960, filed on Oct. 7, 2024, in the Korean Intellectual Property Office, the disclosure of which is incorporated by reference herein in its entirety.

### BACKGROUND

### 1. Field

Embodiments of the disclosure relate to a semiconductor apparatus manufactured by using epitaxial growth, and a method of manufacturing the semiconductor apparatus.

### 2. Description of Related Art

Forming a new single-crystal layer on a single-crystal substrate is called epitaxial growth, and such a new single-crystal layer formed during this process is called an epitaxial layer. Regarding epitaxial growth, a single-crystal substrate and an epitaxial layer may be composed of the same material (homoepitaxy) or different materials (heteroepitaxy). In either cases, lattice constants of materials of the single-crystal substrate and the epitaxial layer should be the same or similar.

However, when attempting to epitaxially grow Group III-V luminescent materials having a large lattice constant difference, dislocation occurs, and this dislocation lowers efficiency of a device.

### SUMMARY

Provided are a semiconductor apparatus manufactured by using epitaxial growth technology that replaces a growth mask with a two-dimensional material layer and a method of manufacturing the semiconductor apparatus.

According to an aspect of the disclosure, a method of manufacturing a semiconductor apparatus may include: forming a two-dimensional material layer on a substrate layer, wherein the substrate layer includes a nitrogen (N)-polar nitride compound material; forming a plurality of through-holes in the two-dimensional material layer along a thickness direction of the two-dimensional material layer by performing a heat treatment at a process temperature in a process gas atmosphere; epitaxially growing a first semiconductor layer along the thickness direction in the plurality of through-holes of the two-dimensional material layer; and performing epitaxial lateral over-growing, horizontally along a plane perpendicular to the thickness direction, of the first semiconductor layer on the two-dimensional material layer.

The nitride compound material of the substrate layer may include at least one of indium (In), gallium (Ga), aluminum (Al), and scandium (Sc), and the N included in the nitride compound material may include a polarity of a −c plane, the −c plane being a (000-1) plane positioned above the at least one of In, Ga, Al, and Sc.

The substrate layer may include at least one of GaN, AlN, InN, AlGaN, InGaN, AlInN, InAlGaN, ScN, GaScN, AlScN, InScN, GaAlScN, GaInScN, AlInScN, and GaAlInScN.

The two-dimensional material layer may have a thickness of 0.5 nm to 30 nm along the thickness direction of the two-dimensional material layer.

Each of the plurality of through-holes may have a diameter of 1 nm to 500 nm.

The two-dimensional material layer may include at least one from among graphene, boron nitride (BN), and transition metal dichalcogenides (TMDs).

A process gas of the process gas atmosphere may include hydrogen gas and ammonia gas, and the process temperature may be 900° C. to 1300° C.

The forming the two-dimensional material layer may include forming the two-dimensional material layer in a process pressure of 50 torr to 500 torr.

The forming the two-dimensional material layer may include forming the two-dimensional material layer in a process time of 1 second to 30 minutes.

Diameters of the plurality of through-holes may be proportional to the process temperature, a flow rate of process gas of the process gas atmosphere, and a time of the heat treatment.

An arrangement density of the plurality of through-holes on one side of the two-dimensional material layer may be proportional to the process temperature, a flow rate of process gas of the process gas atmosphere, and a time of the heat treatment.

The first semiconductor layer may include at least one of GaN, AlN, InN, AlGaN, InGaN, AlInN, InAlGaN, ScN, GaScN, AlScN, InScN, GaAlScN, GaInScN, AlInScN, and GaAlInScN.

The method may further include epitaxially growing a second semiconductor layer on top of the first semiconductor layer.

The second semiconductor layer may include at least one of GaN, AlN, InN, AlGaN, InGaN, AlInN, InAlGaN, ScN, GaScN, AlScN, InScN, GaAlScN, GaInScN, AlInScN, and GaAlInScN.

The method may further include sequentially forming, on top of the second semiconductor layer, a third semiconductor layer and a fourth semiconductor layer.

The first semiconductor layer and the second semiconductor layer may be p-type semiconductor layers, the fourth semiconductor layer may be an n-type semiconductor layer, and the third semiconductor layer may be an active layer.

According to an aspect of the disclosure, a semiconductor apparatus may include: a substrate layer include a nitrogen (N)-polar nitride compound material; a two-dimensional material layer on the substrate layer in a first direction, the two-dimensional material layer including a plurality of through-holes; and a semiconductor device, wherein the semiconductor device may include: a first clad layer over the plurality of through-holes and the two-dimensional material layer in the first direction, the first clad layer including a first conductivity type; an active layer on the first clad layer in the first direction; and a second clad layer on the active layer in the first direction, the second clad layer including a second conductivity type that is electrically opposite to the first conductivity type.

The nitride compound material of the substrate layer may include at least one of indium (In), gallium (Ga), aluminum (Al), and scandium (Sc), and the N included in the nitride compound material may have a polarity of a −c plane, wherein the −c plane is a (000-1) plane positioned above the at least one of the In, Ga, Al, and Sc.

The two-dimensional material layer may include at least one from among graphene, boron nitride (BN), and transition metal dichalcogenides (TMDs).

The two-dimensional material layer may have a thickness of 0.5 nm to 30 nm along a thickness direction of the two-dimensional material layer.

Each of the plurality of through-holes may have a diameter of 1 nm to 500 nm.

According to an aspect of the disclosure, a semiconductor apparatus may include: a substrate layer including a nitrogen (N)-polar nitride compound material; a two-dimensional material layer on a top surface of the substrate layer, wherein two-dimensional material layer includes a plurality of through-holes that extend in a thickness direction of the two-dimensional material layer; and a first semiconductor layer including: a first portion in the plurality of through-holes of the two-dimensional material layer; and a second portion on a top surface of the two-dimensional material layer, the second portion extending horizontally along a plane perpendicular to the thickness direction.

Additional aspects will be set forth in part in the description which follows and, in part, will be apparent from the description, or may be learned by practice of the presented embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a schematic configuration of a semiconductor apparatus according to an embodiment;

FIG. 2 is a cross-sectional view showing a method of manufacturing a semiconductor apparatus, according to an embodiment;

FIG. 3A is a view of a hexagonal crystal structure according to an embodiment;

FIG. 3B is a view of an atomic structure with nitrogen-polarity and gallium-polarity, according to an embodiment;

FIGS. 4A and 4B are each a cross-sectional view showing a method of manufacturing a semiconductor apparatus, according to an embodiment;

FIG. 5 is a cross-sectional view showing a method of manufacturing a semiconductor apparatus, according to a comparative example;

FIG. 6 shows Raman spectrum data of a substrate on which a two-dimensional material layer according to an embodiment is arranged and a substrate on which a two-dimensional material layer according to a comparative example is arranged;

FIGS. 7 to 9A are each a cross-sectional view showing a method of manufacturing a semiconductor apparatus, according to an embodiment;

FIG. 9B is a schematic view of an atomic structure having a substrate layer, a two-dimensional material layer, and a first semiconductor layer, according to an embodiment;

FIG. 10A is a scanning electron microscope (SEM) image of a semiconductor apparatus according to an embodiment;

FIG. 10B is an SEM image of a semiconductor apparatus according to a comparative example;

FIG. 11A is an SEM image of a semiconductor apparatus according to an embodiment;

FIG. 11B is an SEM image of a semiconductor device according to an example, by magnifying a region shown in FIG. 11A.

FIGS. 12 to 14 are each a cross-sectional view showing a method of manufacturing a semiconductor apparatus according to an embodiment;

FIG. 15 is a schematic block diagram showing a configuration of a LiDAR apparatus according to an embodiment; and

FIGS. 16 and 17 are each a conceptual view showing a case in which a LiDAR apparatus including a light-emitting device according to an embodiment is applied to a vehicle.

### DETAILED DESCRIPTION

Reference will now be made in detail to embodiments of the disclosure, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a semiconductor apparatus and a method of manufacturing the same will be described in detail with reference to the accompanying drawings. In the drawings, the same reference numerals denote the same components, and the size of each component in the drawings may be exaggerated for clarity and convenience of description. In addition, embodiments described below are illustrative examples of embodiments, and various changes in forms and details may be made.

Hereinafter, when a component or the like is referred to as being “above” or “on” another component, the component can be directly on the other component or above the other component in a non-contact manner. An expression used in the singular encompasses the expression of the plural, unless it has a clearly different meaning in the context. In addition, when a portion “includes” an element, another element may be further included, rather than excluding the existence of the other element, unless otherwise described.

The use of the term “the” and similar referents is construed to cover both the singular and the plural. Unless the order of steps constituting the method is explicitly stated or stated to the contrary, these steps may be performed in any suitable order, and are not necessarily limited to the order described.

Connections of lines or connecting members between components shown in the drawings are examples of functional connections and/or physical or circuit connections, which can be replaced in actual devices or shown as additional various functional connections, physical connections, or as circuit connections.

Use of all examples and terms are simply for explaining non-limiting example embodiment of the disclosure in detail, and the scope of the disclosure is not limited due to these examples and terms.

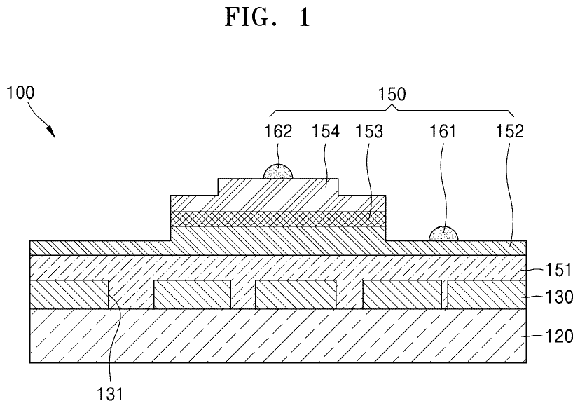

FIG. 1 is a cross-sectional view of a schematic configuration of a semiconductor apparatus according to an embodiment.

Referring to FIG. 1, a semiconductor apparatus 100 may include a substrate layer 120 (e.g., a substrate) having a polarity, a two-dimensional material layer 130 arranged on the substrate layer 120, and a semiconductor device 150. In an embodiment, when the semiconductor device 150 included in the semiconductor apparatus 100 is a light-emitting device, the semiconductor apparatus 100 may serve as a light source. For convenience of explanation, the following description assumes that the semiconductor device 150 included in the semiconductor apparatus 100 is a light-emitting device, but the disclosure is not limited thereto. Depending on the type of the semiconductor device 150 included in the semiconductor apparatus 100, the semiconductor apparatus 100 may serve as a device other than a light source.

As described above, in an embodiment where the substrate layer 120 having a polarity is located under the two-dimensional material layer 130, a semiconductor crystal may be epitaxially grown on the two-dimensional material layer 130. As the polarity of the substrate layer 120 may be stronger, a force that induces the growth of the semiconductor crystal on the two-dimensional material layer 130 may be increased. Accordingly, a semiconductor crystal having a crystal structure according to the crystal direction of the substrate layer 120 may be grown on the two-dimensional material layer 130 without direct chemical bonding with the substrate layer 120 at the bottom of the semiconductor apparatus 100. In this case, the semiconductor crystal grown on the two-dimensional material layer 130 may be a high-quality single crystal having a relatively low dislocation density because the semiconductor crystal is not chemically bonded to the substrate layer 120 at the bottom of the semiconductor apparatus 100, and the stresses may be relieved by the two-dimensional material layer 130.

Hereinafter, a method of epitaxially growing a semiconductor crystal on the two-dimensional material layer 130 in an embodiment where the substrate layer 120 having a polarity is located under the two-dimensional material layer 130 will be described.

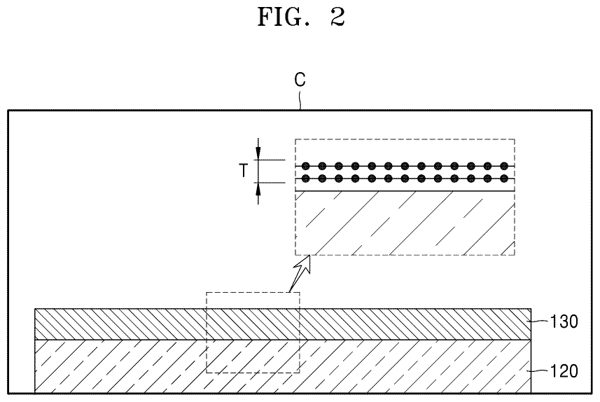

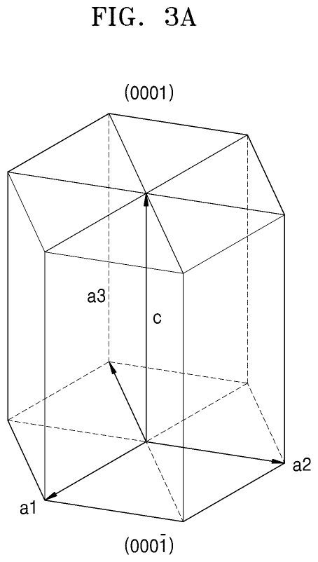

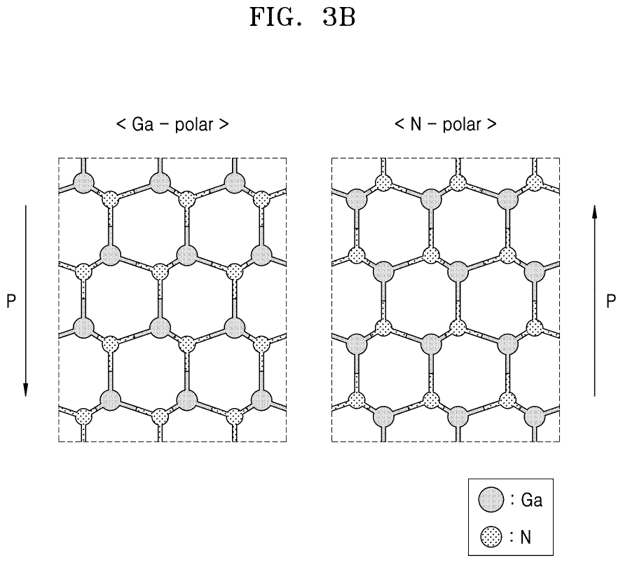

FIG. 2 is a cross-sectional view showing a method of manufacturing a semiconductor apparatus, according to an embodiment. FIG. 3A is a view of a hexagonal crystal structure according to an embodiment. FIG. 3B is a view of an atomic structure with nitrogen-polarity and gallium-polarity according to an embodiment.

Referring to FIG. 2, the substrate layer 120 may be placed inside a reaction chamber C. The substrate layer 120 may extend along one plane, and may be an N-polar single crystal substrate of a Group III-N compound semiconductor. The substrate layer 120 may be provided in a flat shape having a thickness (e.g., a constant thickness).

In an embodiment, the substrate layer 120 may include a single crystal of an N-polar nitride compound semiconductor. For example, when the substrate layer 120 is a GaN substrate, polarity inversion may be induced by doping with magnesium (Mg) at a concentration of about 10¹⁹ cm⁻³ to about 10²⁰ cm⁻³. Accordingly, the substrate layer 120 may exhibit N-polar polarity on the-c plane with a (000-1) plane direction. In an embodiment, as shown in FIG. 3A, N atoms in a GaN material having a hexagonal crystal structure may be exposed on the surface of the (000-1) plane perpendicular to the C-axis. Accordingly, as shown in FIG. 3B, N-polar polarity in which N atoms are mainly exposed on the surface of GaN crystals may be expressed. When the substrate layer 120 exhibits the N-polar polarity, the substrate layer 120 may have excellent electrical properties including relatively high electron mobility and high breakdown voltage.

In an embodiment, the substrate layer 120 may include one or more from among GaN, AlN, InN, AlGaN, InGaN, AlInN, InAlGaN, ScN, GaScN, AlScN, InScN, GaAlScN, GaInScN, AlInScN, and GaAlInScN. Here, the nitride compound material included in the substrate layer 120 may include one or more from among In, Ga, Al, and Sc, and the N included in the nitride compound material of the substrate layer 120 may provide N-polar polarity on a (−c) plane, which is a (000-1) plane located above In, Ga, Al, and Sc.

The two-dimensional material layer 130 may be provided to have a thickness (e.g., a constant thickness), and then arranged on top of the substrate layer 120. In other words, the two-dimensional material layer 130 may be arranged on the upper surface of the substrate layer 120 where the growth of the semiconductor device 150 (e.g., a light-emitting device) shown in FIG. 1 will begin. The two-dimensional material layer 130 may have, for example, a thickness T of about 0.5 nm to about 10 nm. The two-dimensional material layer 130 may have a thickness T of about 0.5 nm to about 30 nm.

The two-dimensional material layer 130 may include a two-dimensional crystal having a hexagonal crystal structure. The two-dimensional material layer 130 may include, for example, one or more from among graphene, boron nitride (BN), and transition metal dichalcogenides that are compounds of transition metals and chalcogen elements. The transition metal dichalcogenide may be represented by MX₂ (where M is a transition metal, and X is a chalcogen element), and may include, for example, one or more from among MoS₂, WS₂, TaS₂, HfS₂, ReS₂, TiS₂, NbS₂, SnS₂, MoSe₂, WSe₂, TaSe₂, HfSe₂, ReSe₂, TiSe₂, NbSe₂, SnSe₂, MoTe₂, WTe₂, TaTe₂, HfTe₂, ReTe₂, TiTe₂, NbTe₂, and SnTe₂. The two-dimensional material layer 130 may be transferred as a monolayer, a bilayer, or multiple layers, on the upper surface of the substrate layer 120. However, the disclosure is not limited to the embodiments described herein, and the two-dimensional material layer 130 may be grown directly on the substrate layer 120 using a direct growth method, or may be arranged on the substrate layer 120 using a liquid coating method or the like.

In an embodiment, a chemical vapor deposition process for manufacturing the semiconductor apparatus, such as a metal organic chemical vapor deposition (MOCVD) process, may be performed in a high-temperature process atmosphere. When the substrate layer 120 according an embodiment is an N-polar single crystal substrate of a Group III-N compound semiconductor, thermal decomposition of the substrate layer 120 may occur in a high-temperature process atmosphere. Here, when ammonia (NH₃) is injected as the process gas, processes of desorbing N-containing radicals (hereinafter referred to as N-radicals) from the substrate layer 120, reabsorbing and bonding back to the substrate layer 120 may occur continuously, resulting in the substrate layer 120 appearing to be retained or undergo a very slow etching process.

When the two-dimensional material layer 140 is arranged on top of the substrate layer 120 according to an embodiment, self-decomposition may occur in a local area by N-radicals generated in the process of thermal decomposition of the substrate layer 120. By adjusting the local area where self-decomposition occurs, a plurality of through-holes 131 may be formed in the two-dimensional material layer 130 without a separate patterning process.

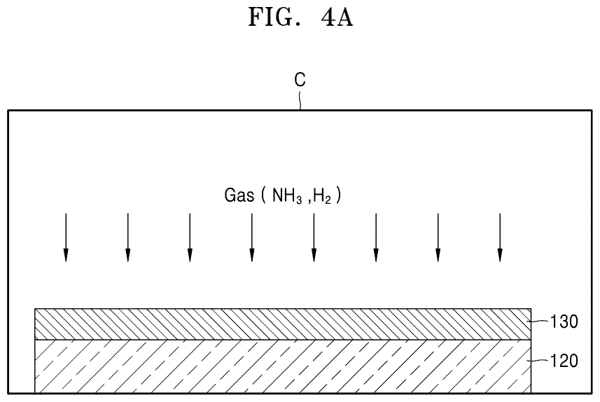

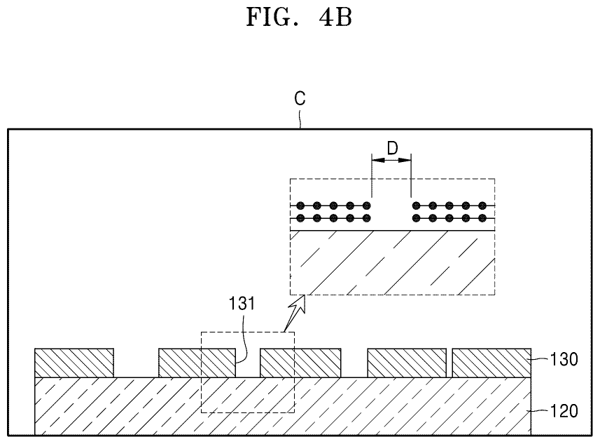

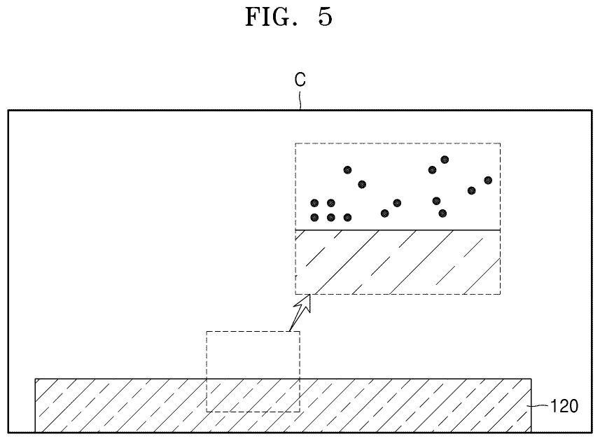

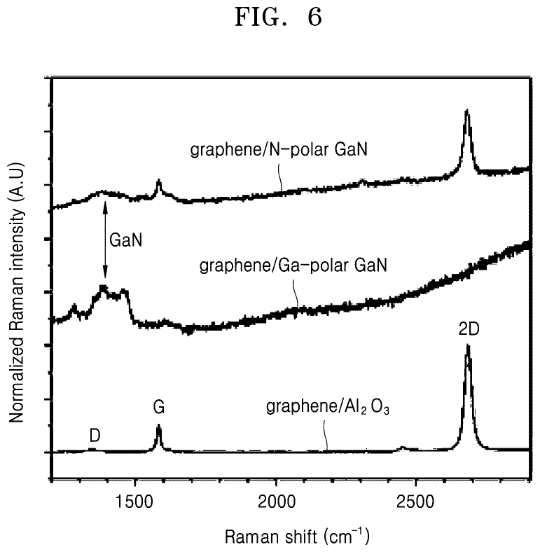

FIGS. 4A and 4B are each a cross-sectional view showing a method of manufacturing a semiconductor apparatus, according to an embodiment. FIG. 5 is a cross-sectional view showing a method of manufacturing a semiconductor apparatus, according to a comparative example. FIG. 6 shows Raman spectrum data of a substrate on which a two-dimensional material layer is arranged according to an embodiment and a substrate on which a two-dimensional material layer is arranged according to a comparative example.

Referring to FIGS. 4A and 4B, process gas may be supplied into a reaction chamber C in which the two-dimensional material layer 130 is arranged on top of the substrate layer 120. For use as the process gas for self-decomposition on a local area of the two-dimensional material layer 130, ammonia (NH₃) gas and hydrogen (H₂) gas may be used. However, the disclosure is not limited thereto, and H₂ gas may be excluded from being used as a process gas, or mixed gas further including argon (Ar) gas or nitrogen (N₂) gas in addition to H₂ gas and NH₃ gas may be supplied to be used as the process gas.

In addition, the process pressure for self-decomposition of the two-dimensional material layer 130 may be about 50 torr to about 500 torr. However, this is only an example and other process pressures may be used.

The volume ratio of N-source gas to H₂ gas applied into the reaction chamber C may be, for example, about 1:50. Here, the volume ratio of the N-source gas and the H₂ gas included in the process gas may be appropriately adjusted according to the self-decomposition conditions (e.g., a process temperature, a process pressure, etc.).

Next, a heat treatment process may be performed by raising the internal temperature of the reaction chamber C to a temperature using a heating source. The process temperature for self-decomposition of the two-dimensional material layer 130 may be about 900° C. to about 1300° C. For example, when the inside of the reaction chamber C is a hydrogen atmosphere, the process temperature may be about 900° C. to about 1200° C. In addition, when the inside of the reaction chamber C is a nitrogen atmosphere, the process temperature may be about 1000° C. to about 1300° C. However, the disclosure is not limited thereto, and the heat treatment process may be performed at different process temperatures depending on the atmosphere of the process gas.

In an embodiment, the heat treatment process on the substrate layer 120 and the two-dimensional material layer 130 may last for about 1 second to about 30 minutes. However, the disclosure is not limited thereto, and the heat treatment process may be performed at different process times depending on the atmosphere of the process gas and the process temperatures.

When the substrate layer 120 is an N-polar single crystal substrate of a Group III-N compound semiconductor, such as an N-polar GaN substrate, thermal decomposition of the substrate layer 120 may occur in a high-temperature atmosphere, causing desorption of N-radicals. Accordingly, the two-dimensional material layer 130 may be damaged by the N-radicals. Here, by using NH₃ injected as the process gas, processes of reabsorbing of the N-radicals and bonding back to the substrate layer 120 may occur continuously, resulting in the substrate layer 120 being retained or undergoing a very slow etching process.

Damage may occur in a local area of the two-dimensional material layer 130 by the N-radicals. As a process time elapses, such damage occurring in a local area may create a plurality of through-holes 131 extending along the thickness direction of the two-dimensional material layer 130. In an embodiment, each of the plurality of through-holes 131 may be formed as a nano-pore having a diameter D of several nanometers (nm) to several hundred nm. In an embodiment, the diameter D of each of the plurality of through-holes 131 may be about 1 nm to about 500 nm. In an embodiment, the diameter D of each of the plurality of through-holes 131 may be about 1 nm to about 50 nm. In an embodiment, the diameter D of each of the plurality of through-holes 131 may be about 10 nm to about 500 nm.

In an embodiment, the diameter D of the plurality of through-holes 131 and the arrangement density of the plurality of through-holes 131 may increase in proportion to the process temperature. Here, the arrangement density of the plurality of through-holes 131 may be defined as the total area of the plurality of through-holes 131 arranged on one side of the two-dimensional material layer 130 relative to the total area of the one side of the two-dimensional material layer 130. In addition, the diameter D of the plurality of through-holes 131 and the arrangement density of the plurality of through-holes 131 may be inversely proportional to the process pressure. In addition, the diameter D of the plurality of through-holes 131 and the arrangement density of the plurality of through-holes 131 may increase in proportion to the process time. The diameter D of the plurality of through-holes 131 and the arrangement density of the plurality of through-holes 131 may increase in proportion to the flow rate of the process gas such as, for example, the flow rate of hydrogen gas.

As described above, when adjusting the process temperature, process time, process pressure, and flow rate of process gas, the two-dimensional material layer 130 on which a plurality of through-holes 131 (e.g., nanopore-sized through-holes) are patterned may be formed.

When a separate patterning process such as, for example, a manufacturing process of a growth mask, is performed, the two-dimensional material layer 130 in which a plurality of through-holes 131 of several micrometers in size are arranged may be formed. Meanwhile, in an embodiment, without performing a separate patterning process, the two-dimensional material layer 130 in which a plurality of through-holes 131 (e.g., nanopore-sized through-holes) are arranged may be formed during a metal organic chemical vapor deposition (MOCVD) process. Accordingly, not only may the manufacturing process be simplified, but also, by forming the two-dimensional material layer 130 in which a plurality of through-holes 131 (e.g., nano-sized through-holes) are arranged, the expansion of dislocation defects may be effectively prevented, thereby forming a large-area dislocation-free region.

Meanwhile, referring to FIGS. 3B and 5 according to a comparative example, the substrate layer 120 may include single crystals of a gallium-polar (Ga-polar) nitride compound semiconductor. A heat treatment process for patterning the two-dimensional material layer 130 may be the same as the heat treatment process according to an embodiment described in connection with FIGS. 4A and 4B.

According to a comparative example, when the substrate layer 120 on which the two-dimensional material layer 130 is arranged includes single crystals of a Ga-polar nitride compound semiconductor, in other words, when the Ga atoms in GaN crystals of the substrate layer 120 are exposed on the surface, the thermal decomposition stability may be lower than the N-polar nitride compound semiconductor. Accordingly, as can be seen in the Raman spectrum of FIG. 6, it is confirmed that the two-dimensional material layer 130 arranged on top of the substrate layer 120, which undergoes a heat treatment process according to the comparative example (graphene/Ga-polar GaN), is completely destroyed and thus does not exist. That is, it is confirmed that the two-dimensional material layer 130 can remain only when the N-polar substrate (graphene/N-polar GaN) according to an embodiment is used, or when a nitride substrate is not used such as, for example, when a sapphire substrate (graphene/Al₂O₃) is used. In this regard, without a separate patterning process, such as a manufacturing process of a growth mask, the two-dimensional material layer 130 in which a plurality of through-holes 131 (e.g., nanopore-sized through-holes) are arranged cannot be formed on the substrate layer 120 including single crystals of the Ga-polar nitride compound semiconductor.

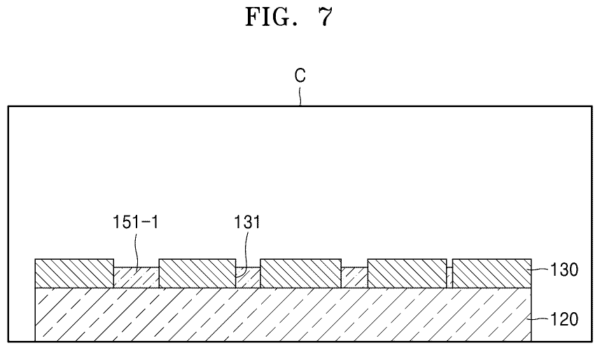

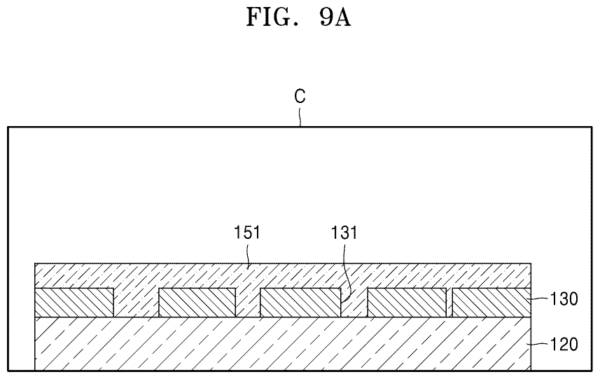

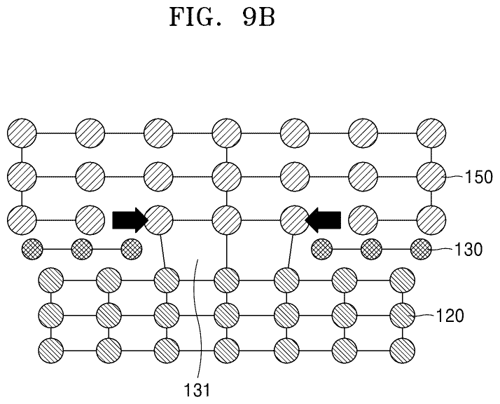

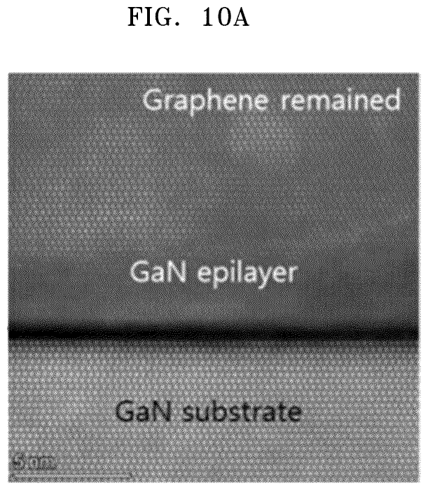

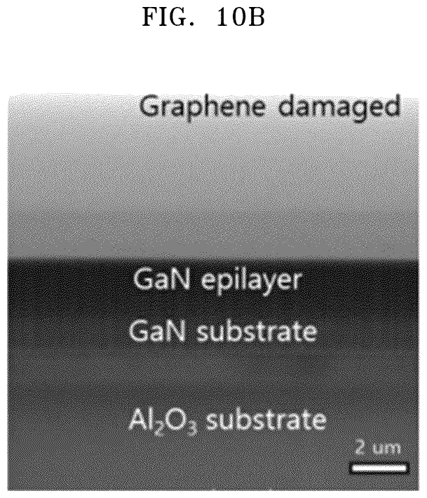

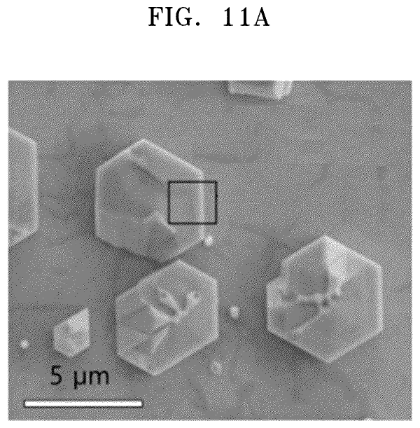

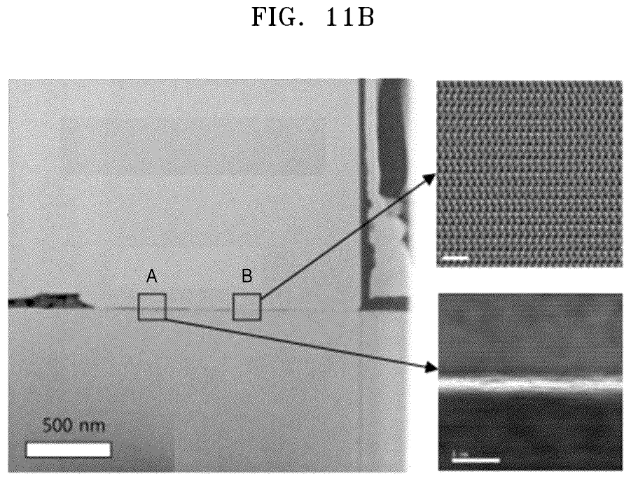

FIGS. 7 to 9A are each a cross-sectional view showing a method of manufacturing a semiconductor apparatus according to an embodiment. FIG. 9B is a schematic view of an atomic structure having the substrate layer, the two-dimensional material layer, and a first semiconductor layer, according to an embodiment. FIG. 10A is a scanning electron microscope (SEM) image of a semiconductor apparatus according to an embodiment. FIG. 10B is an SEM image of a semiconductor apparatus according to a comparative example. FIG. 11A is an SEM image of a semiconductor apparatus according to an embodiment. FIG. 11B an SEM image of a semiconductor device according to an example, by magnifying a region shown in FIG. 11A.

Referring to FIGS. 7 to 9A, the two-dimensional material layer 130 according to an embodiment may have a pattern shape in which a plurality of through-holes 131 are arranged. A first semiconductor layer 151 may undergo epitaxial lateral over-growth along the thickness direction of the two-dimensional material layer 130 and along a plane perpendicular to the thickness direction, in each of the plurality of through-holes 131 arranged in the two-dimensional material layer 130.

The first semiconductor layer 151 according to an embodiment may be epitaxially grown by any one of the following processes: an MOCVD method, a hydride vapor phase epitaxy (HVPE) method, a pulsed laser deposition (PLD) method, a molecular beam epitaxy (MBE) method, a hydrothermal synthesis method, a liquid phase epitaxy (LPE) method, and an ammonothermal method.

When the first semiconductor layer 151 is formed on the two-dimensional material layer 130 by using an MOCVD method according to an embodiment, ammonia gas and hydrogen gas may be supplied into the reaction chamber C at flow rates of 2 slm and 3 slm, respectively. Here, the process temperature may be in a range of about 400° C. to about 1200° C. In addition, the process pressure may be in a range of about 50 Torr to about 500 Torr. Here, the process time may be in a range of about 5 minutes to about 30 minutes.

Referring to FIG. 7, a first portion 151-1 of the semiconductor layer 151 may be epitaxially grown along the thickness direction of the two-dimensional material layer 130, in each of the plurality of through-holes 131 arranged on the two-dimensional material layer 130. Referring to FIGS. 11A and 11B, an enlarged SEM image of a region B of the first portion 151-1 of the semiconductor layer 151 grown in an area where the plurality of through-holes 131 are arranged is shown.

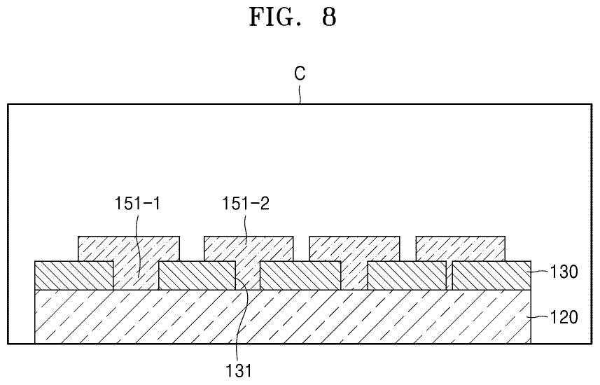

Next, referring to FIG. 8, a second portion 151-2 of the semiconductor layer 151 according to an embodiment may be epitaxially grown on the two-dimensional material layer 130, in a horizontal direction along a plane perpendicular to the thickness direction of the two-dimensional material layer 130. Referring to FIGS. 11A and 11B, an enlarged SEM image of a region A of the first portion 151-1 of the semiconductor layer 151 grown on the two-dimensional material layer 130 is shown.

Next, referring to FIG. 9A, the first semiconductor layer 151 according to an embodiment may be epitaxially grown on the two-dimensional material layer 130 to cover the two-dimensional material layer 130. In an embodiment, the first semiconductor layer 151 may include one or more from among GaN, AlN, InN, AlGaN, InGaN, AlInN, InAlGaN, ScN, GaScN, AlScN, InScN, GaAlScN, GaInScN, AlInScN, and GaAlInScN.

In an embodiment, as shown in FIG. 10A, it is confirmed that a first semiconductor layer 151 (e.g., a GaN epilayer) is arranged on graphene which is a two-dimensional material layer 130. Here, a substrate (e.g., the substrate layer 120, such as a GaN substrate) on which the two-dimensional material layer 130 is arranged may be a N-polar GaN substrate. However, in the case of FIG. 10B according to a comparative example, it is confirmed that a first semiconductor layer (e.g., a GaN epilayer as the first semiconductor layer 151) is directly arranged on top of a Ga-polar substrate layer (e.g., the substrate layer 120, such as a GaN substrate), and that a graphene layer, which is the two-dimensional material layer 130, has been annihilated and no longer exists.

In an embodiment, since first portion 151-1 of the semiconductor layer 151 may be epitaxially grown in each of the plurality of through-holes 131 (e.g., nanopore-sized through-holes), as shown in FIG. 9B, stress may be locally formed only in a very small area between the first portion 151-1 of the semiconductor layer 151 and the substrate layer 120. Furthermore, in the case of the second portion 151-2 of the semiconductor layer 151 that undergoes epitaxial lateral over-growth horizontally on the two-dimensional material layer 130 along a plane perpendicular to the thickness direction of the two-dimensional material layer 130, the substrate layer 120 and the second portion 151-2 of the semiconductor layer 151 may be spatially separated by the two-dimensional material layer 130, thereby forming a stress-relieving structure. The stress may be relieved by the two-dimensional material layer 130, and thus single crystals with a relatively dislocation density may be formed. In other words, as the mosaicity is reduced, the crystalline perfection may be improved, and an InGaN layer with a relatively high amount of indium components (indium-rich InGaN) may be accordingly formed.

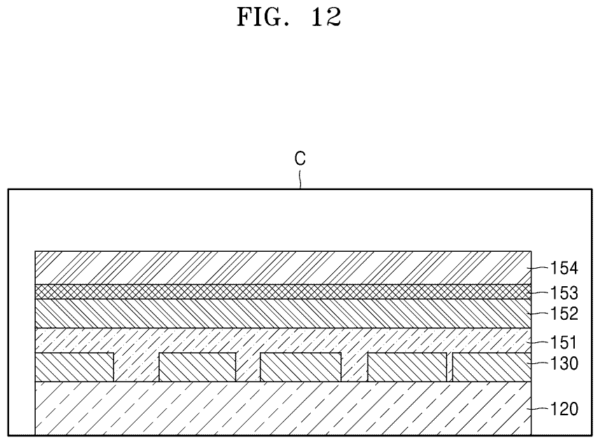

FIGS. 12 to 14 are each a cross-sectional view showing a method of manufacturing a semiconductor apparatus according to an embodiment.

Referring to FIG. 12, a second semiconductor layer 152 may be formed on the first semiconductor layer 151. The second semiconductor layer 152 may be grown in a horizontal direction as well as a vertical direction. In an embodiment, the second semiconductor layer 152 may be grown in a horizontal direction and then arranged on the first semiconductor layer 151. In an embodiment, the second semiconductor layer 152 may include one or more from among GaN, AlN, InN, AlGaN, InGaN, AlInN, InAlGaN, ScN, GaScN, AlScN, InScN, GaAlScN, GaInScN, AlInScN, and GaAlInScN. The second semiconductor layer 152 may be formed at a temperature higher than the process temperature of the first semiconductor layer 151 such as, for example, at a temperature in a range of about 1020° C. to about 1150° C. Accordingly, the second semiconductor layer 152 may form a higher quality semiconductor layer than the first semiconductor layer 151. However, the disclosure is not limited thereto, and a third semiconductor layer 153, which will be described later, may be formed directly on the first semiconductor layer 151 without forming the second semiconductor layer 152.

Next, the third semiconductor layer 153 may be formed on the second semiconductor layer 152. The third semiconductor layer 153 may be grown in a horizontal direction as well as a vertical direction. In an embodiment, the third semiconductor layer 153 may be grown in a horizontal direction and then arranged on the second semiconductor layer 152.

Next, a fourth semiconductor layer 154 may be formed on the third semiconductor layer 153. The fourth semiconductor layer 154 may be grown in a horizontal direction as well as a vertical direction.

In an embodiment, when the semiconductor device 150 is a light-emitting device, the first semiconductor layer 151 and the second semiconductor layer 152 may be first clad layers doped with a first conductivity type. The first clad layers (e.g., the first semiconductor layer 151 and the second semiconductor layer 152) may be semiconductors having a first conductivity type such as, for example, p-type semiconductors. The first clad layers (e.g., the first semiconductor layer 151 and the second semiconductor layer 152) may include various p-type doped Group III-V compound semiconductor materials. For example, the first clad layers (e.g., the first semiconductor layer 151 and the second semiconductor layer 152) may be doped to be a p-type (e.g., a p-type semiconductor layer), and include one or more from among GaN, AlN, InN, AlGaN, InGaN, AlInN, InAlGaN, ScN, GaScN, AlScN, InScN, GaAlScN, GaInScN, AlInScN, and GaAlInScN.

In addition, the fourth semiconductor layer 154 may be a second clad layer doped with a second conductivity type that is electrically opposite to the first conductivity type. The second clad layer (e.g., the fourth semiconductor layer 154) may be, for example, an n-type semiconductor having a second conductivity type that is electrically opposite to the first conductivity type. The second clad layer (e.g., the fourth semiconductor layer 154) may be doped to be an n-type (e.g., an n-type semiconductor layer), and include one or more from among GaN, AlN, InN, AlGaN, InGaN, AlInN, InAlGaN, ScN, GaScN, AlScN, InScN, GaAlScN, GaInScN, AlInScN, and GaAlInScN.

In addition, the third semiconductor layer 153 arranged between the second semiconductor layer 152 and the fourth semiconductor layer 154 may be an active layer. Such an active layer (i.e., the third semiconductor layer 153) may include only one quantum well, or may include a multi-quantum well (MQW) in which multiple quantum wells and multiple barriers are arranged alternately. When the third semiconductor layer 153 serving as the active layer includes a material having an MQW structure, the active layer (i.e., the third semiconductor layer 153) may have a structure in which quantum layers and well layers are stacked alternately. The third semiconductor layer 153 serving as the active layer may include various Group III-V compound semiconductor materials. The third semiconductor layer 153 serving as the active layer may include, for example, InP, AlGaN, AlInGaN, GaAs, GaN, or the like.

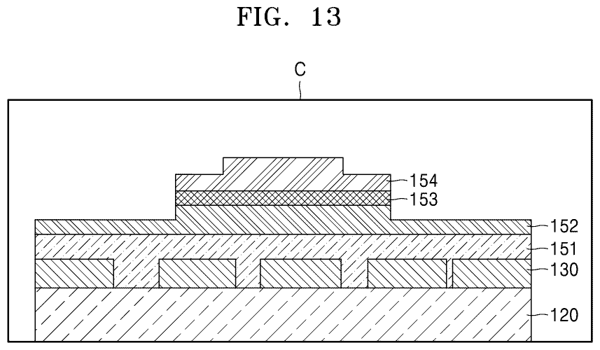

Referring to FIG. 13, the width of the semiconductor device 150 may be adjusted by an etching process. Here, an etching process may be performed so that the widths of the first semiconductor layer 151 and the second semiconductor layer 152 become greater than the width of the third semiconductor layer 153, and the width of the third semiconductor layer 153 becomes greater than the width of a portion (e.g., an upper portion) of the fourth semiconductor layer 154.

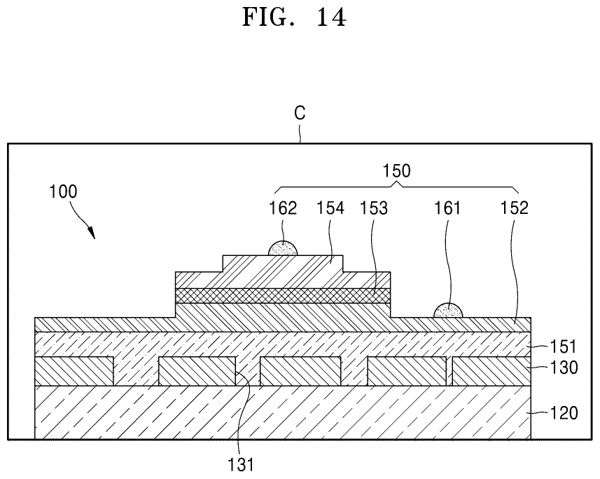

Referring to FIG. 14, a first electrode 161 may be formed on the second semiconductor layer 152, and a second electrode 162 may be formed on the fourth semiconductor layer 154. The first electrode 161 may be a p-type electrode, and the second electrode 162 may be an n-type electrode. According to an embodiment, a contact layer may be arranged between the second semiconductor layer 152 and the first electrode 161. In addition, a contact layer may be arranged between the fourth semiconductor layer 154 and the second electrode 162.

In FIG. 14, the semiconductor device 150 may be a laser diode (LD). However, embodiments of the disclosure are not limited thereto, and the semiconductor device 150 may include, for example, a light-emitting diode (LED).

In addition, a semiconductor apparatus 100 may further include, as the semiconductor device 150, various optical devices in addition to the light-emitting device.

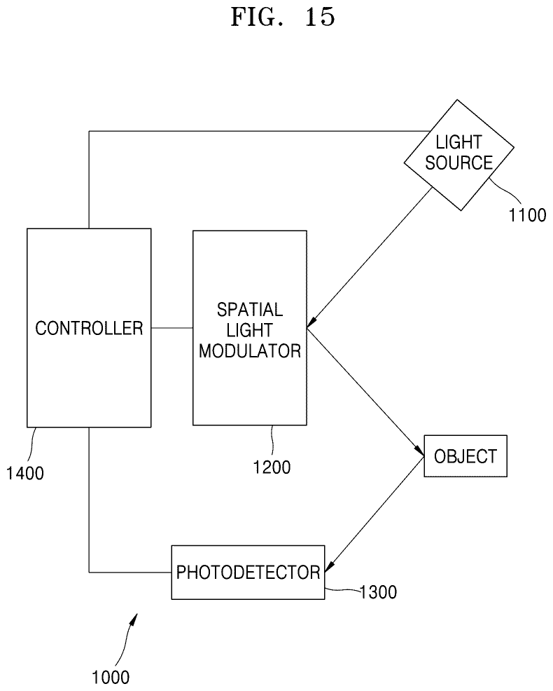

FIG. 15 is a schematic block diagram showing a configuration of a LiDAR apparatus 1000 according to an embodiment.

Referring to FIG. 15, a LiDAR apparatus 1000 according to an embodiment may include a light source 1100 that emits light, a spatial light modulator 1200 that adjusts the traveling direction of the light emitted from the light source 1100 in the direction of an object and emits light onto the object, a photodetector 1300 that detects light reflected from the object, wherein the traveling direction of the light has been adjusted in the spatial light modulator 1200, and a controller 1400 that controls the spatial light modulator 1200.

The light source 1100 may include, as the light source, the semiconductor apparatus 100 of FIG. 1. The light source 1100 may be, for example, a laser diode (LD). However, embodiments of the disclosure are not limited thereto, and the light source 1100 may include various light sources such as, for example, a light-emitting diode (LED) that emits visible light.

The spatial light modulator 1200 may control the traveling direction of light by modulating the phase for each pixel. The modulating of the phase for each pixel may be sequentially controlled, and thus the traveling direction of light may be sequentially adjusted to scan an object. The spatial light modulator 1200 may be used as a beam steering device with high optical efficiency and therefore with low power consumption.

The controller 1400 may control operation of the light source 1100, the spatial light modulator 1200, and the photodetector 1300. For example, the controller 1400 may control on/off operation of the light source 1100, on/off operation of the photodetector 1300, beam scanning operation of the spatial light modulator 1200. In addition, the controller 1400 may calculate information about an object based on the measurement results obtained by the photodetector 1300.

The LiDAR apparatus of FIG. 15 may be a phase-shift type apparatus or a time-of-flight (TOF) apparatus.

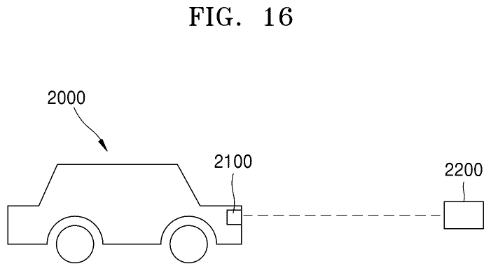

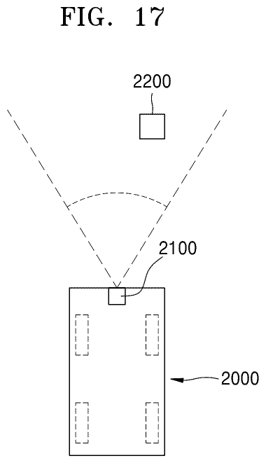

FIGS. 16 and 17 are each a conceptual view showing a case in which a LiDAR apparatus 2100 (e.g., the LiDAR apparatus 1000) including a light-emitting device according to an embodiment is applied to a vehicle 2000. FIG. 16 is a side view of the vehicle 2000 equipped with the LiDAR apparatus 2100, and FIG. 17 is a top view of the of the vehicle 2000 equipped with the LiDAR apparatus 2100.

Referring to FIG. 16, the LiDAR apparatus 2100 may be applied to a vehicle 2000, and information about a subject 2200 may be obtained by using the LiDAR apparatus 2100. The vehicle 2000 may be a car having autonomous driving capabilities. By using the LiDAR apparatus 2100, an object or person (i.e., the subject 2200) present in the direction in which the vehicle 2000 is moving may be detected. In addition, by using information such as a time difference between a transmission signal and a detection signal, the distance to the subject 2200 may be measured. In addition, as shown in FIG. 17, information on the subject 2200 that is either nearby or distant within a scanning range may be obtained.

According to one or more embodiments of the disclosure, a semiconductor apparatus utilizing epitaxial growth and a method of manufacturing the same have been described with reference to the example embodiments shown in the drawings, but these are merely examples, and those skilled in the art will understand that various modifications and equivalent other embodiments of the disclosure can be made therefrom. Therefore, the example embodiments described herein are to be considered in an descriptive point of view rather than a restrictive point of view.

According to embodiments of the disclosure, by replacing a growth mask with a two-dimensional material layer, a method of manufacturing a semiconductor apparatus using epitaxial growth technology with improved manufacturing process convenience and reduced cost may be provided.

In addition, according to embodiments of the disclosure, a semiconductor apparatus with low dislocation density and low interface stress may be provided by using epitaxial growth technology.

It should be understood that example embodiments described herein should be considered in a descriptive sense only and not for purposes of limitation. Descriptions of features or aspects within each embodiment of the disclosure should typically be considered as available for other similar features or aspects in other embodiments of the disclosure. While one or more example embodiments have been described with reference to the figures, it will be understood by those of ordinary skill in the art that various changes in form and details may be made therein without departing from the spirit and scope of the disclosure.

What is claimed is:

1. A method of manufacturing a semiconductor apparatus, the method comprising:
forming a two-dimensional material layer on a substrate layer, wherein the substrate layer comprises a nitrogen (N)-polar nitride compound material;
forming a plurality of through-holes in the two-dimensional material layer along a thickness direction of the two-dimensional material layer by performing a heat treatment at a process temperature in a process gas atmosphere;
epitaxially growing a first semiconductor layer along the thickness direction in the plurality of through-holes of the two-dimensional material layer; and
performing epitaxial lateral over-growing, horizontally along a plane perpendicular to the thickness direction, of the first semiconductor layer on the two-dimensional material layer.

2. The method of claim 1, wherein the nitride compound material of the substrate layer comprises at least one of indium (In), gallium (Ga), aluminum (Al), and scandium (Sc), and
wherein the N included in the nitride compound material includes a polarity of a −c plane, the −c plane being a (000-1) plane positioned above the at least one of In, Ga, Al, and Sc.

3. The method of claim 2, wherein the substrate layer comprises at least one of GaN, AlN, InN, AlGaN, InGaN, AlInN, InAlGaN, ScN, GaScN, AlScN, InScN, GaAlScN, GaInScN, AlInScN, and GaAlInScN.

4. The method of claim 1, wherein the two-dimensional material layer has a thickness of 0.5 nm to 30 nm along the thickness direction of the two-dimensional material layer.

5. The method of claim 1, wherein each of the plurality of through-holes has a diameter of 1 nm to 500 nm.

6. The method of claim 1, wherein the two-dimensional material layer comprises at least one of graphene, boron nitride (BN), and transition metal dichalcogenides (TMDs).

7. The method of claim 1, wherein a process gas of the process gas atmosphere comprises hydrogen gas and ammonia gas, and the process temperature is 900 °C. to 1300 °C.

8. The method of claim 7, wherein the forming the two-dimensional material layer comprises forming the two-dimensional material layer in a process pressure of 50 torr to 500 torr.

9. The method of claim 7, wherein the forming the two-dimensional material layer comprises forming the two-dimensional material layer in a process time of 1 second to 30 minutes.

10. The method of claim 1, wherein diameters of the plurality of through-holes are proportional to the process temperature, a flow rate of process gas of the process gas atmosphere, and a time of the heat treatment.

11. The method of claim 1, wherein an arrangement density of the plurality of through-holes on one side of the two-dimensional material layer is proportional to the process temperature, a flow rate of process gas of the process gas atmosphere, and a time of the heat treatment.

12. The method of claim 1, wherein the first semiconductor layer comprises at least one of GaN, AlN, InN, AlGaN, InGaN, AlInN, InAlGaN, ScN, GaScN, AlScN, InScN, GaAlScN, GaInScN, AlInScN, and GaAlInScN.

13. The method of claim 1, further comprising epitaxially growing a second semiconductor layer on top of the first semiconductor layer.

14. The method of claim 13, wherein the second semiconductor layer comprises at least one of GaN, AlN, InN, AlGaN, InGaN, AlInN, InAlGaN, ScN, GaScN, AlScN, InScN, GaAlScN, GaInScN, AlInScN, and GaAlInScN.

15. The method of claim 13, further comprising sequentially forming, on top of the second semiconductor layer, a third semiconductor layer and a fourth semiconductor layer.

16. The method of claim 15, wherein the first semiconductor layer and the second semiconductor layer are p-type semiconductor layers, the fourth semiconductor layer is an n-type semiconductor layer, and the third semiconductor layer is an active layer.

17. A semiconductor apparatus comprising:
a substrate layer comprising a nitrogen (N)-polar nitride compound material;
a two-dimensional material layer on the substrate layer, the two-dimensional material layer comprising a plurality of through-holes; and
a semiconductor device,
wherein the semiconductor device comprises:
a first clad layer over the plurality of through-holes and the two-dimensional material layer, the first clad layer comprising a first conductivity type;
an active layer on the first clad layer; and
a second clad layer on the active layer, the second clad layer comprising a second conductivity type that is electrically opposite to the first conductivity type.

18. The semiconductor apparatus of claim 17, wherein the nitride compound material of the substrate layer comprises at least one of indium (In), gallium (Ga), aluminum (Al), and scandium (Sc), and
wherein the N included in the nitride compound material has a polarity of a −c plane, wherein the −c plane is a (000-1) plane positioned above the at least one of the In, Ga, Al, and Sc.

19. The semiconductor apparatus of claim 17, wherein the two-dimensional material layer has a thickness of 0.5 nm to 30 nm along a thickness direction of the two-dimensional material layer.

20. The semiconductor apparatus of claim 17, wherein each of the plurality of through-holes has a diameter of 1 nm to 500 nm.
